(19) United States
(12) Patent Application Publication
(10) Pub. No.: US 2025/0017079 A1
(43) Pub. Date: Jan. 9, 2025

(54) Display Device

(71) Applicant: LG Display Co., Ltd., Seoul (KR)

(72) Inventor: Sungsik Son, Paju-si (KR)

(21) Appl. No.: 18/760,973

(22) Filed: Jul. 1, 2024

(30) Foreign Application Priority Data
Jul. 7, 2023 (KR) 10-2023-0088158

(51) Int. Cl. H10K 59/80

(52) U.S. Cl. CPC H10K 59/872

(57) ABSTRACT

Disclosed is a display device, including: a display panel; and a plate including a lower surface portion disposed on a lower surface of the display panel and side surface portions connected to the lower surface portion and disposed on side surfaces of the display panel, and the side surface portions may be disposed on at least three side surfaces of the display panel.

### CROSS REFERENCE TO RELATED APPLICATION

The present application claims priority to Republic of Korea Patent Application No. 10-2023-0088158, filed Jul. 7, 2023, which is hereby incorporated by reference in its entirety.

### FIELD

The present disclosure relates to a display device.

### BACKGROUND

With the development of an information-oriented society, various demands for display devices for displaying images have increased, and various types of display devices, such as liquid crystal display devices, and organic light emitting display devices have been used.

The display device includes a display panel, and the display panel may include a liquid display panel or an organic light emitting display panel etc. according to a type of the display device.

Meanwhile, the organic light emitting display panel includes a substrate and organic light emitting didoes disposed on the substrate, and if the substrate is formed as a rigid substrate made of glass or quartz, light generated from the organic light emitting diodes may leak through a side surface of the rigid substrate (light leakage on a side surface).

### SUMMARY

An object of the present disclosure is to provide a display device capable of improving leakage of light generated from the organic light emitting diode through the side surface of the rigid substrate (light leakage on a side surface).

The problem of the present disclosure is not limited to the above-mentioned problem, and other technical problems may be inferred from embodiments disclosed below.

One embodiment is a display device, including: a display panel; and a plate including a lower surface portion disposed on a lower surface of the display panel and side surface portions connected to the lower surface portion and disposed on side surfaces of the display panel, and the side surface portions may be disposed on at least three side surfaces of the display panel.

Another embodiment is a display device, including: an organic light-emitting display panel including a rigid substrate and a light-emitting diode layer on the rigid substrate; and a plate including a lower surface portion disposed on a lower surface of the organic light-emitting display panel and side surface portions connected to the lower surface portion and disposed on side surfaces of the display panel, and light generated from the light-emitting diode layer may be leaked through a side surface of the rigid substrate, and the side surface portion may be configured to cover the side surface of the rigid substrate.

Other details of the embodiment is included in the detailed description and the accompanying drawings.

According to the embodiments, it is possible to prevent or at least reduce the phenomenon of light leakage on the rigid substrate of the display device.

In addition, it is possible to reduce constituent components and material costs because the display device may prevent or at least reduce light leakage by extending a plate, which serves to dissipate heat or reinforce intensity in the related art, to a side surface of the display panel without disposing a separate housing outside the display panel.

In addition, it is possible to facilitate material cost reduction by using a rigid substrate as a lower substrate of the display panel.

Moreover, it is possible to prevent or at least reduce the phenomenon of light leakage in the display panel by separately disposing a light-leaking prevention member on an edge portion, in which a side surface portion of a plate configured to support a lower portion of the display panel is not disposed.

Furthermore, it is possible to prevent or at least reduce wrinkling of the plate by buffering thermal deformation of the plate because the light-leaking prevention member includes a material having a high coefficient of thermal expansion compared to that of the plate.

Also, it is possible to prevent or at least reduce light leakage through an interval space between the display panel and a second portion of the side surface portion by applying a first light-shielding pattern in the non-display area of the cover window.

In addition, it is possible to absorb light leaking on a side surface of the display panel by disposing a second light-shielding pattern on an inner side surface of the side surface portion.

Moreover, it is possible to prevent or at least reduce light leakage through the interval space between a second portion of the side surface portion and the display panel through a third light-shielding pattern between a third bonding member, configured to bond the cover window and the display panel, and the side surface portion to each other.

Furthermore, it is possible to prevent or at least reduce light leakage in an edge portion because a second side surface portion located on a side surface on an upper side of the display panel extends more toward side surface portions located on side surfaces on left and right sides.

In addition, it is possible to prevent light leakage on the side surface and minimize or at least reduce physical interference with a flexible circuit film because a side surface portion is disposed on one side surface to which the flexible circuit film of the display panel is attached and the side surface portion is disposed between the flexible circuit films.

The effects of the present invention are not limited to the above-described effects and other effects which are not described herein may be derived by those skilled in the art from the following description of the embodiments of the present invention.

### BRIEF DESCRIPTION OF THE DRAWINGS

FIG. 1 is a perspective view of a display device according to an embodiment.

FIG. 2 is a view schematically illustrating a process for manufacturing a plate according to FIG. 1 according to an embodiment.

FIG. 3 is a plan view of a display device according to FIG. 1 according to an embodiment.

FIG. 4 is a cross-sectional view taken along the line A-A′ in FIG. 3 according to an embodiment.

FIG. 5 is a cross-sectional view taken along the line B-B′ in FIG. 3 according to an embodiment.

FIG. 6 is a cross-sectional view taken along the line C-C′ in FIG. 3 according to an embodiment.

FIG. 7 is a cross-sectional view of a display panel according to an embodiment.

FIG. 8 is an enlarged cross-sectional view of a Q1 area in FIG. 4 according to an embodiment.

FIG. 9 is a cross-sectional view of a display device according to a comparative embodiment.

FIG. 10 is a perspective view of a display device according to another embodiment.

FIG. 11 is a perspective view of a plate and a light-leaking prevention member of a display device according to FIG. 10 according to an embodiment.

FIG. 12 is a cross-sectional view of a display device according to FIG. 10 according to an embodiment.

FIG. 13 is a cross-sectional view of a display device according to still another embodiment.

FIG. 14 is a cross-sectional view of a display device according to still another embodiment.

FIG. 15 is an enlarged cross-sectional view of a Q2 area in FIG. 13 according to an embodiment.

FIG. 16 is a cross-sectional view of a display device according to still another embodiment.

FIG. 17 is a cross-sectional view of a display device according to still another embodiment.

FIG. 18 is an enlarged cross-sectional view of a Q3 area in FIG. 16 according to an embodiment.

FIG. 19 is a cross-sectional view of a display device according to still another embodiment.

FIG. 20 is a perspective view of a plate according to still another embodiment.

FIG. 21 is an enlarged perspective view of a Q4 area in FIG. 20 according to an embodiment.

FIG. 22 is a plan view of a display device according to still another embodiment.

FIG. 23 is a cross-sectional view taken along the line D-D′ in FIG. 22 according to an embodiment.

### DETAILED DESCRIPTION

Hereinafter, embodiments of the invention will be described with reference to the drawings. In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description. “And/or” includes all of one or more combinations defined by related components.

It will be understood that the terms “first” and “second” are used herein to describe various components but these components should not be limited by these terms. The above terms are used only to distinguish one component from another. For example, a first component may be referred to as a second component and vice versa without departing from the scope of the invention. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawing.

In various embodiments of the invention, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

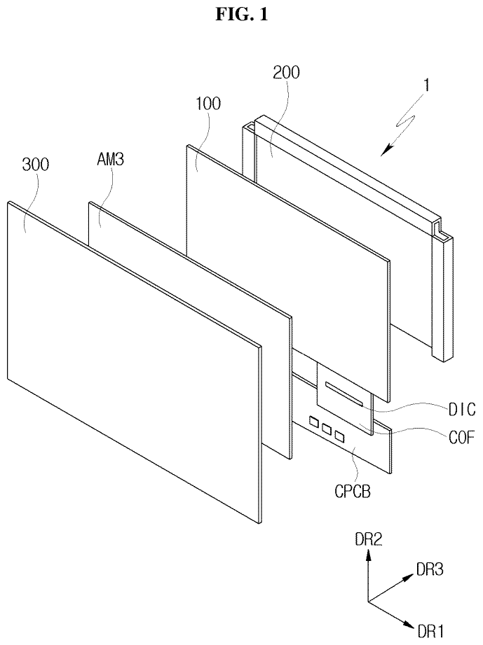

FIG. 1 is a perspective view of a display device according to an embodiment.

Referring to FIG. 1, the display device 1 may include a display panel 100, a plate 200 below the display panel 100, and a cover window 300 on the display panel 100. The display panel 100 may be an organic light emitting panel. In the embodiments, a first direction DR1 and a second direction DR2 are different directions and intersect each other, for example, refer to directions intersecting perpendicularly in a plan view. A third direction DR3 is a direction intersecting a plane in which the first direction DR1 and the second direction DR2 lie, for example, a direction perpendicularly intersecting both the first direction DR1 and the second direction DR2. In FIG. 1, the first direction DR1 indicates a direction in which long sides of the display panel 100 extend, the second direction DR2 indicates a direction in which short sides of the display panel 100 extend, and the third direction DR3 indicates a direction in which the plate 200, the display panel 100, and the cover window 300 are stacked. However, directions mentioned in exemplary embodiments should be understood as relative directions, and the exemplary embodiments are not limited to the mentioned directions.

For example, the display panel 100 may take the form of a rectangle including long sides extending along the first direction DR1 and short sides extending along the second direction DR2. However, the shape of the display panel 100 is not limited thereto, and may be a quadrangle, a circle, an oval, or other polygon. Hereinafter, for convenience of description, the description will be provided in an assumption that the display panel 100 takes the form of a rectangle. An edge of the display panel 100 may include an angular shape or a round shape.

In an end on the other side in the second direction DR2 of the display panel 100, a printed circuit film COF may be attached. An end on one side in the second direction DR2 of the printed circuit film COF may be attached to the display panel 100. A data controller DIC may be mounted on the printed circuit film COF. The data controller DIC may be implemented in a form of a chip, but is not limited thereto, and may be formed on the printed circuit film COF in a form of a circuit. In an end on the other side in the second direction DR2 of the printed circuit film COF, a source printed circuit board CPCB may be attached. The printed circuit film COF may be provided in plurality, and may be spaced apart from each other in the first direction DR1.

The plate 200 may be disposed below the display panel 100. The plate 200 may be disposed below the display panel 100 to support the display panel 100. The plate 200 may serve to dissipate heat generated from the display panel 100 to the outside. Therefore, the plate 200 may include a metal material having excellent thermal conductivity. For example, the metal material may include aluminum, but is not limited thereto. In one embodiment, the plate 200 may be disposed not only below the display panel 100, but also in a side portion of the display panel 100, thereby preventing a phenomenon of light leakage, by which light leaked from the side portion of the display panel 100 is leaked outside. The plate 200 may be disposed on at least three side surfaces of the display panel 100. For example, the plate 200 may be disposed on a side surface on a long side in the second direction DR2, and side surfaces on one side and the other side, which are short sides in the first direction DR1 in the display panel 100. A function of light leakage prevention of the plate 200 will be described below in detail.

The cover window 300 may be disposed on the display panel 100. The cover window 300 is disposed on the display panel 100 to protect the display panel 100. The cover window 300 may be made of a rigid material including glass or quartz, or a plastic material. The cover window 300 may extend more outward than the side surfaces of the display panel 100. That is, the cover window 300 may fully cover the display panel 100.

The cover window 300 may be disposed on the display panel 100 through a third bonding member AM3 disposed between the display panel 100 and the cover window 300. The third bonding member AM3 may include a light-transparent resin (OCR), or a light-transparent adhesive (OCA). The third bonding member AM3 may not deteriorate light transmittance when light generated from the display panel 100 is displayed on the outside through the cover window 300, because the third bonding member AM3 includes a light-transparent resin (OCR), or a light-transparent adhesive (OCA).

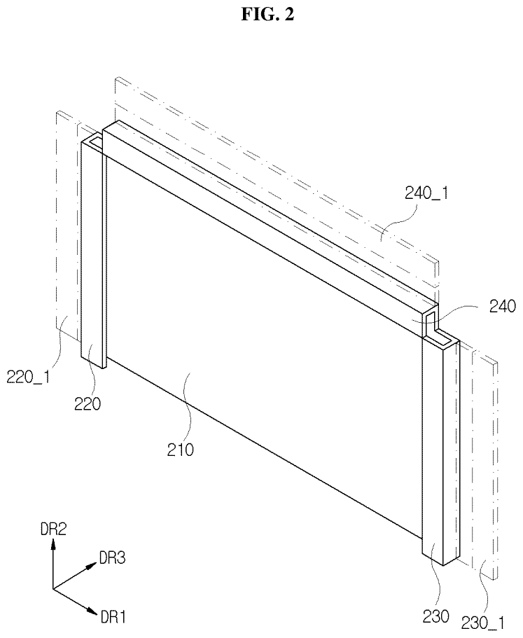

FIG. 2 is a view schematically illustrating a process for manufacturing the plate according to FIG. 1 according to an embodiment.

Referring to FIGS. 1 and 2, the plate 200 may include a lower surface portion 210 overlapping the display panel 100, and side surface portions 220, 230 and 240, each of which extending from the lower surface portion 210. The lower surface portion 210 may be disposed on a lower surface of the display panel 100 and cover the lower surface of the display panel 100, and each of the side surface portions 220, 230 and 240 may be disposed on side surfaces of the display panel 100 and may cover the side surfaces of the display panel 100. In an embodiment, each of the side surface portions 220, 230 and 240 may be formed to surround a side surface of the display panel 100. The side surface portions 220, 230 and 240 may include a first side surface portion 220 extending toward the other side in the first direction DR1 of the lower surface portion 210, a second side surface portion 220 extending toward one side in the first direction DR1 of the lower surface portion 210, and a third side portion 240 extending toward one side in the second direction DR2 of the lower surface portion 210. Each of the side surface portions 220, 230 and 240 may have a bent shape as described below. In an embodiment, the first side surface portion 220, the second side surface portion 230, and the third side portion 240 may be integrally formed with the lower surface portion 210 by bending a single plate, i.e., plate 200. Meanwhile, the adjacent side surface portions 220, 230 and 240 may not be connected and may be separated from each other. That is, each of the side surface portions 220, 230 and 240 may be connected to the lower surface portion 210, and the adjacent side surface portions 220, 230 and 240 may not be physically connected to each other. Since the adjacent side surface portions 220, 230 and 240 are not physically connected to each other, empty spaces may be formed in edge portions (an edge portion on the other side in the first direction DR1 and on one side in the second direction DR2, an edge portion on one side in the first direction DR1 and on one side in the second direction DR2). As in the embodiment, the adjacent side surface portions 220, 230 and 240 are not physically connected to each other, the side surface portions 220, 230 and 240 may be easily formed. In more detail, as illustrated in FIG. 2, each of the side surface portions 220, 230 and 240 may be bent in a U-shape from an unfolded state (refer to 220_1, 230_1, 240_1). If empty spaces are not formed in the edge portions of the lower surface portion 210 (the edge portion on the other side in the first direction DR1 and on one side in the second direction DR2, the edge portion on one side in the first direction DR1 and on one side in the second direction DR2) as the embodiment, when each of the side surface portions 220, 230 and 240 is bent in a U-shape from the unfolded state (220_1, 230_1, 240_1), the edge portions may wrinkle and the manufacture of the side surface portions may not be easy. However, as in the embodiment, empty spaces are formed in the edge portions of the lower surface portion 210 (the edge portion on the other side in the first direction DR1, the edge portion on one side in the second direction DR2, the edge portion on one side in the first direction DR1 and the edge portion on one side in the second direction DR2) because the adjacent side surface portions 220, 230 and 240 are not physically connected to each other, therefore, the manufacture of the side surface portions 220, 230 and 240 bent in a U-shape may be made easier.

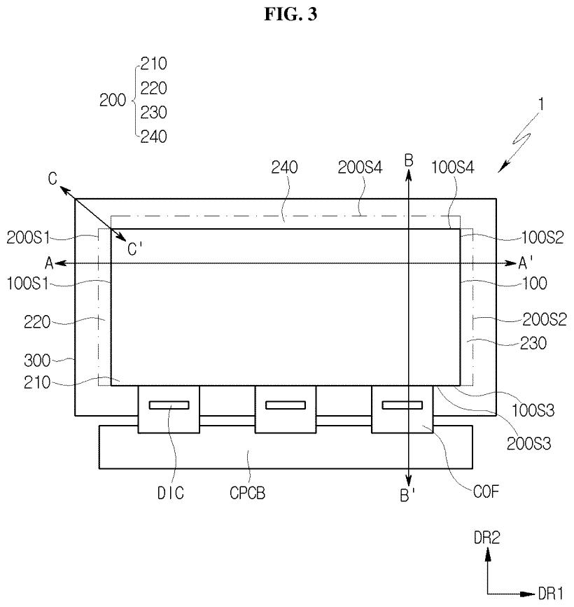

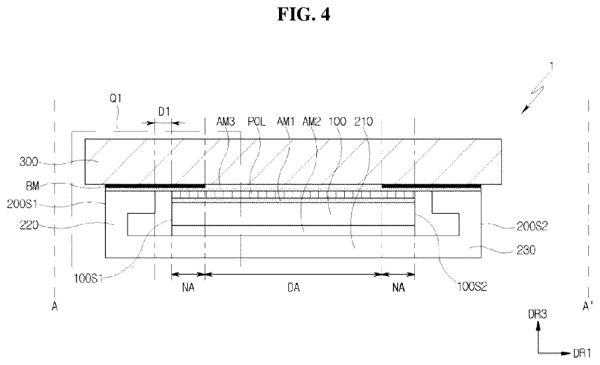

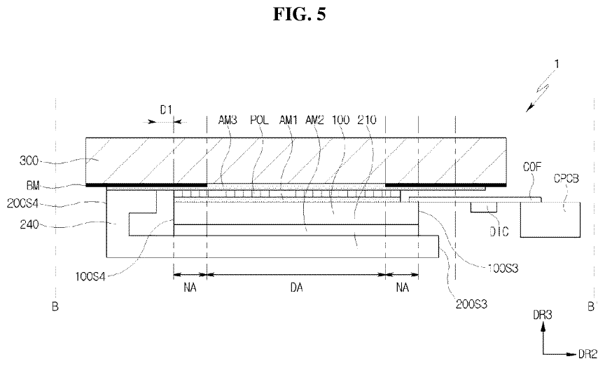

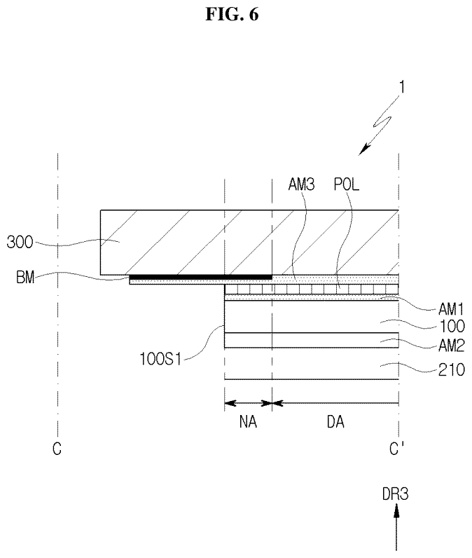

FIG. 3 is a plan view of a display device according to FIG. 1 according to an embodiment. FIG. 4 is a cross-sectional view taken along the line A-A′ in FIG. 3 according to an embodiment. FIG. 5 is a cross-sectional view taken along the line B-B′ in FIG. 3 according to an embodiment. FIG. 6 is a cross-sectional view taken along the line C-C′ in FIG. 3 according to an embodiment.

Referring to FIG. 1 and FIGS. 3 to 6, the display panel 100 may include side surfaces 100S3 and 100S4 on long sides, and side surfaces 100S1 and 100S2 on short sides. The plate 200 may include each of side surfaces 200S1, 200S2, 200S3 and 200S4, which are disposed adjacent to the side surfaces 100S3 and 100S4 on long sides, and the side surfaces 100S1 and 100S2 on short sides of the display panel. The side surfaces 100S1 and 100S2 on short sides of the display panel 100 may include a first panel side surface 100S1 disposed on one side in the first direction DR1, and a second panel side surface 100S2 disposed on the other side in the first direction DR1, and the side surfaces 100S3 and 100S4 on long sides of the display panel 100 may include a third panel side surface 100S3 disposed on one side in the second direction DR2 and a fourth panel side surface 100S4 disposed on the other side in the second direction DR2. The plate 200 includes the lower surface portion 210 overlapping the display panel 100, and the side surface portions 220, 230 and 240, each of which extends outward from the lower surface portion 210. The side surface 200S1 of the first side surface portion 220 may be adjacent to the first panel side surface 100S1, the side surface 200S2 of the second side surface portion 230 may be adjacent to the second panel side surface 100S2, and the side surface 200S3 of the third side surface portion 240 may be adjacent to the third panel side surface 100S3. Each of the side surface 200S1 of the first side surface portion 220, the side surface 200S2 of the second side surface portion 230 and the side surface 200S3 of the third side surface portion 240 may extend more outward than the adjacent panel side surfaces 100S1, 100S2 and 100S3, respectively. Accordingly, each of the side surface portions 220, 230 and 240 may be disposed more outward than the panel side surfaces 100S1, 100S2 and 100S3 of the display panel 100, respectively, and may cover the panel side surfaces 100S1, 100S2 and 100S3, respectively.

As illustrated in FIGS. 3 to 5, the display device 1 may further include a polarization member POL disposed on the display panel 100, a first bonding member AM1 disposed between the display panel 100 and the polarization member POL, and a second bonding member AM2 disposed between the display panel 100 and the lower surface portion 210. The lower surface portion 210 may overlap the first bonding member AM1, the second bonding member AM2, the polarization member POL, the third bonding member AM3, and the cover window 300. The lower surface portion 210 may overlap a part of the first light-shielding pattern BM. In addition, the side surface portions 220, 230 and 240 may overlap the third bonding member AM3, the other part of the first light-shielding pattern BM, and the cover window 300. The first bonding member AM1 may bond the display panel 100 and the polarization member POL to each other. The first bonding member AM1 may include one material among the above-mentioned materials of the third bonding member AM3. The polarization member POL may be disposed over the display panel 100 and may reduce external light reflection. The polarization member POL is widely known in the art; therefore, the detailed description thereof will be omitted.

The third bonding member AM3 between the polarization member POL and the cover window 300 may serve to bond the polarization member POL and the cover window 300 to each other. The first bonding member AM1 may be disposed in the display area DA and the non-display area NA, and on the other hand, the third bonding member AM3 may extend more outward than the first bonding member AM1. The cover window 300 may extend more outward than the side surfaces 100S1, 100S2, 100S3 and 100S4 of the display panel 100. The first light-shielding pattern BM may be disposed below the cover window 300. The first light-shielding pattern BM may be directly printed on a bottom surface of the cover window 300. The first light-shielding pattern BM may include a light-shielding material. For example, the light-shielding material may include a light-absorbing material. The light-absorbing material may include a black pigment, or a black dye, but is not limited thereto.

The first light-shielding pattern BM may be disposed on portions, in the non-display area NA and the cover window 300, extending more outward than the side surfaces 100S1, 100S2, 100S3 and 100S4 of the display panel 100. In the portions extending more outward than the side surfaces 100S1, 100S2, 100S3 and 100S4 of the display panel 100, the third bonding member AM3 may be disposed between the first light-shielding member BM and each of the side surface portions 220, 230 and 240 so as to bond the third bonding member AM3 to each of the side surface portions 220, 230 and 240, and in the display area DA, the third bonding member AM3 may bond the cover window 300 and the polarization member POL to each other. As will be described below, the side surface portions 220 to 240 may include the second portions (refer to 220b of the first side surface portion 220), and the second portions may be bonded to the third bonding member AM3.

The first light-shielding pattern BM may overlap the lower surface portion 210, the side surface portions 220, 230 and 240, the bonding members AM1, AM2 and AM3, the non-display area NA of the display panel 100, the cover window 300, and the polarization member POL. In addition, the first light-shielding pattern BM may overlap the printed circuit film COF, and the data controller DIC.

The second bonding member AM2 may be disposed in the display area DA, and may bond the display panel 100 and the lower surface portion 210 to each other.

As illustrated in FIGS. 2, 3 and 6, empty spaces may be formed in the edge portions (the edge portion on the other side in the first direction DR1 and on one side in the second direction DR2, the edge portion on one side in the first direction DR1 and on one side in the second direction DR2) of the lower surface portion 210. Therefore, in the edge portions (the edge portion on the other side in the first direction DR1 and on one side in the second direction DR2, the edge portion on one side in the first direction DR1 and on one side in the second direction DR2) of the lower surface portion 210, side surfaces (or edge portions) of the display panel 100 may be exposed to the outside. Description of the components (210, AM2, AM1, POL, AM3, and 300) of the display device 1 in FIG. 6 has been provided with reference to FIGS. 4 and 5, and the detailed description thereof will be omitted.

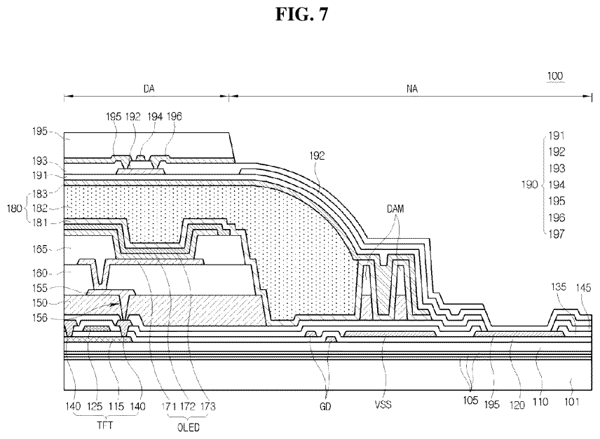

FIG. 7 is a cross-sectional view of the display panel according to an embodiment.

Referring to FIG. 7, thin film transistors TFT configured to drive light emitting diodes OLED may be disposed in the display area AA on a substrate 101. The substrate 101 may be a rigid substrate which includes a rigid material. The rigid material may include glass or quartz, for example. That is, the substrate 101 may be a transparent substrate A refractive index of the substrate 101 may be about 1.5, but is not limited thereto. The light transmittance of the substrate 101 which includes the rigid material may be higher than that of the substrate which includes a flexible material. A thickness of the substrate 101 including the rigid material may be greater than that of the substrate including the flexible material. In an embodiment, the substrate 101 includes the rigid substrate having a higher intensity, and thus, may better support components disposed on the upper part, and may reduce material costs compared to the above-mentioned substrate including the flexible material.

A circuit layer CEL may be disposed on the substrate 101. The circuit layer CEL may include a buffer layer 105, a first insulating layer 110, thin film transistors TFT, a gate driver GD, a low potential driving power line VSS, a second insulating layer 120, a touch electrode 105, a third insulating layer 135, a fourth insulating layer 145, a first intermediate layer 150, a connection electrode 155, and a second intermediate layer 160.

The thin film transistor TFT may include a semiconductor layer 115, a gate electrode 125, a source and a drain electrode 140. The thin film transistor TFT may be a driving transistor. For convenience of description, only driving transistor among various thin film transistors which may be included in the display device has been illustrated, however, other kinds of thin film transistors such as a switching transistor etc. may be included in the display device. In addition, in the present disclosure, it is described that the thin film transistor TFT has a coplanar structure, but the thin film transistor TFT may be implemented to have another structure such as a staggered structure etc., without limitation thereto.

As illustrated in FIG. 7, the thin film transistor TFT may include the semiconductor layer 115 disposed on the first insulating layer 110, the gate electrode 125 overlapping the semiconductor layer 115 with the second insulating layer 120 interposed therebetween, and the source and drain electrodes 140 formed on the third insulating layer 135 and contacting the semiconductor layer 115.

The semiconductor layer 115 may act as an area where a channel is formed during an operation of the thin-film transistor TFT. The semiconductor layer 115 may be made of an oxide semiconductor, amorphous silicon (a-Si), or polycrystalline silicon (poly-Si), or may be made of various organic semiconductors such as pentacene. The present disclosure is not limited thereto. The semiconductor layer 115 may be formed on the first insulating layer 110. The semiconductor layer 115 may include a channel area, a source area, and a drain area. The channel area may overlap the gate electrode 125 with the first insulating layer 110 interposed therebetween and may be formed between the source and drain electrodes 140. The source area may be electrically connected to the source electrode 140 through a contact hole penetrating the second insulating layer 120 and the third insulating layer 135. The drain area may be electrically connected to the drain electrode 140 through a contact hole penetrating the second insulating layer 120 and the third insulating layer 135. The buffer layer 105 and the first insulating layer 110 may be disposed between the semiconductor layer 115 and the substrate 101. The buffer layer 105 may delay diffusion of moisture and/or oxygen invading into the substrate 101. The first insulating layer 110 may protect the semiconductor layer 115 and may block various types of defects introduced from the substrate 101.

The uppermost layer of the buffer layer 105 that is in contact with the first insulating layer 110 may be made of a material having different etching characteristics from those of each of the remaining layers of the buffer layer 105, the first insulating layer 110, the second insulating layer 120 and the third insulating layer 135. The uppermost layer of the buffer layer 105 contacting the first insulating layer 110 may be made of one of silicon nitride (SiNx) and silicon oxide (SiOx). Each of the remaining layers of the buffer layer 105, the first insulating layer 110, the second insulating layer 120, and the third insulating layer 135 may be made of the other of silicon nitride (SiNx) and silicon oxide (SiOx). For example, the uppermost layer of the buffer layer 105 in contact with the first insulating layer 110 may be made of silicon nitride (SiNx), while each of the remaining layers of the buffer layer 105, the first insulating layer 110, the second insulating layer 120, and the third insulating layer 135 may be made of silicon oxide (SiOx), but the present embodiment is not limited thereto.

The gate electrode 125 may be formed on the second insulating layer 120 and may overlap the channel area of the semiconductor layer 115 with the second insulating layer 120 interposed therebetween. The gate electrode 125 may be made of a first conductive material which is embodied as a single layer or multi-layers made of magnesium (Mg), molybdenum (Mo), aluminum (Al), chromium (Cr), gold (Au), titanium (Ti), nickel (Ni), neodymium (Nd), copper (Cu), or an alloy thereof, but the present disclosure is not limited thereto.

The source electrode 140 may be connected to the source area of the semiconductor layer 115 exposed through the contact hole penetrating the second insulating layer 120 and the third insulating layer 135. The drain electrode 140 may be opposite to the source electrode 140 and may be connected to the drain area of the semiconductor layer 115 through the contact hole penetrating the second insulating layer 120 and the third insulating layer 135. Each of the source and drain electrodes 140 may be made of a second conductive material which is embodied as a single layer or multi-layers made of molybdenum (Mo), aluminum (Al), chromium (Cr), gold (Au), titanium (Ti), nickel (Ni), neodymium (Nd), copper (Cu), or an alloy thereof, but the present disclosure is not limited thereto.

The connection electrode 155 may be disposed between the first intermediate layer 150 and the second intermediate layer 160. The connection electrode 155 may be connected to the drain electrode 140 through a connection electrode contact hole 156 penetrating a protective layer 145 and the first intermediate layer 150. The connection electrode 155 may be made of a material having low resistivity and identical to or similar to that of the drain electrode 140, but is not limited thereto.

A light-emitting diode layer EL may be disposed on the circuit layer CEL. The light-emitting diode layer EL may include the organic light emitting diodes OLED. The light-emitting diode layer EL may include the organic light emitting diodes OLED, and a bank layer 165.

The organic light emitting diodes OLED including a light-emitting layer 172 may be disposed over the second intermediate layer 160 and the bank layer 165. The organic light emitting diodes OLED may include an anode electrode 171, at least one light-emitting layer 172 formed on the anode electrode 171, and a cathode electrode 173 formed on the light-emitting layer 172.

The anode electrode 171 may be disposed over the first intermediate layer 150 through a contact hole penetrating the second intermediate layer 160, and may be electrically connected to the connection electrode 155 exposed to an upper portion of the second intermediate layer 160.

The anode electrode 171 of each pixel is not covered with the bank layer 165. The bank layer 165 may be made of an opaque material (e.g., black) to prevent or at least reduce light interference between adjacent pixels. In this case, the bank layer 165 may include a light-shielding material including at least one of color pigment, organic black, and carbon black. The present disclosure is not limited thereto.

The at least one light-emitting layer 172 may be formed on the anode electrode 171 which corresponds to a light-emitting area defined by the bank layer 165. The at least one light-emitting layer 172 may include a hole transport layer, a hole injection layer, a hole blocking layer, the light-emitting layer 172, an electron injection layer, an electron blocking layer, and an electron transport layer on the anode electrode 171, and the layers may be stacked in this order or a reverse order in accordance with an emission direction. Further, the light-emitting layer 172 may include first and second emission stacks which are opposite to each other with a charge generating layer disposed therebetween. In this case, the light-emitting layer 172 of any one of the first and second emission stacks generates blue light and the light-emitting layer 172 of the other one of the first and second emission stacks generates yellow-green light so that white light may be generated by the first and the second emission stacks. The white light generated in the emission stack is incident onto a color filter located above or below the light-emitting layer 172 to implement color images. As another example, the light-emitting layers 172 may generate color lights corresponding to individual pixels without having separate color filters to implement color images. For example, the light-emitting layer 172 of a red pixel may generate red light, the light-emitting layer 172 of a green pixel may generate green light, and the light-emitting layer 172 of a blue pixel may generate blue light.

The cathode electrode 173 may be formed to be opposite to the anode electrode 171 with the light-emitting layer 172 interposed therebetween, and may be applied with a high potential driving voltage EVDD.

An encapsulating layer 180 blocks moisture or oxygen from invading into the light emitting diodes OLED which is vulnerable to the moisture or oxygen from the outside. To this end, the encapsulating layer 180 may include at least one inorganic encapsulating layer and at least one organic encapsulating layer, but is not limited thereto. In the present disclosure, a structure of the encapsulating layer 180 in which a first encapsulating layer 181, a second encapsulating layer 182, and a third encapsulating layer 183 are sequentially stacked will be described as an example.

The first encapsulating layer 181 is formed over the substrate 101 over which the cathode electrode 173 is formed. The third encapsulating layer 183 is formed over the substrate 101 over which the second encapsulating layer 182 is formed and encloses a top surface, a bottom surface, and a side surface of the second encapsulating layer 182 together with the first encapsulating layer 181. The first encapsulating layer 181 and the third encapsulating layer 183 may minimize or prevent the invasion of external moisture or oxygen into the organic light emitting diodes OLED. The first encapsulating layer 181 and the third encapsulating layer 183 are formed of an inorganic insulating material on which low-temperature deposition is allowed, such as silicon nitride SiNx, silicon oxide SiOx, silicon oxynitride SiON, or aluminum oxide Al2O3. The first encapsulating layer 181 and the third encapsulating layer 183 are deposited under a low temperature atmosphere so that the damage of the organic light emitting diodes OLED which is vulnerable to a high temperature atmosphere may be prevented during the deposition process of the first encapsulating layer 181 and the third encapsulating layer 183.

The second encapsulating layer 182 serves as a buffer which alleviates stress between layers due to the bending of the display device and planarizes a step between layers. The second encapsulating layer 182 may be formed of acryl resin, epoxy resin, phenolic resin, polyamide resin, polyimide resin, and polyethylene or a non-photosensitive organic insulating material such as silicon oxy carbon SiOC, or a photosensitive organic insulating material such as photoacryl, on the substrate 101 over which the first encapsulating layer 181 is formed, but is not limited thereto. When the second encapsulating layer 182 is formed using an inkjet method, a dam DAM may be disposed to prevent a liquefied second encapsulating layer 182 from being diffused to an edge of the substrate 101. The dam DAM may be disposed to be closer to the edge of the substrate 101 than the second encapsulating layer 182. The dam DAM may prevent or at least reduce the second encapsulating layer 182 from being diffused into a pad area where a conductive pad disposed at an outermost periphery of the substrate 101 is disposed.

The dam DAM is designed to prevent or at least reduce the diffusion of the second encapsulating layer 182, however, when the second intermediate layer 182 is formed to extend beyond a height of the dam DAM during the process, the second encapsulating layer 182 which is an organic layer may be exposed to the outside, thereby allowing moisture etc. to easily invade into the light-emitting diodes. Therefore, in order to prevent the invasion of moisture etc., at least ten or more dams DAM may be repeatedly formed.

The dam DAM may be disposed on the protective layer 145 of the non-display area NA.

Further, the dam DAM may be simultaneously formed with the first intermediate layer 150 and the second intermediate layer 160. When the first intermediate layer 150 is formed, a lower layer of the dam DAM is formed together and when the second intermediate layer 160 is formed, an upper layer of the dam DAM is formed together so that the dam DAM may be stacked to have a double-layered structure.

Therefore, the dam DAM may be configured with the same material as the first intermediate layer 150 and the second intermediate layer 160, but is not limited thereto.

The dam DAM may be formed to overlap a low potential driving power line VSS. For example, on a lower layer of a region of the non-display area NA where the dam DAM is located, the low potential driving power line VSS may be formed.

The low potential driving power line VSS and the gate driver GD in a form of a gate in panel (GIP) may surround a periphery of the display panel. The low potential driving power line VSS may be located outside of the gate driver GD. Further, the low potential driving power line VSS may be connected to the anode electrode 171 to apply a common voltage thereto. The gate driver GD is simply illustrated in plan and cross-sectional views. However, the gate driver GD may be configured using a thin-film transistor TFT having the same structure as that of the thin-film transistor TFT of the display area AA.

The low potential driving power line VSS is disposed outside of the gate driver GD. The low potential driving power line VSS is disposed outside of the gate driver GD and surrounds the display area DA. The low potential driving power line VSS may be made of the same material as that of each of the source and drain electrodes 140 of the thin-film transistor TFT, but is not limited thereto. For example, the low potential driving power line VSS may be made of the same material as that of the gate electrode 125.

Further, the low potential driving power line VSS may be electrically connected to the anode electrode 171. The low potential driving power line VSS may supply the low potential driving voltage EVSS to the plurality of pixels in the display area AA.

A touch layer 190 may be disposed on the encapsulating layer 180. On the touch layer 190, a touch buffer layer 191 may be located between a touch sensor metal including touch electrode connecting lines 192 and 194 and touch electrodes 195 and 196, and the cathode electrode 173 of the organic light emitting diode OLED.

The touch buffer layer 191 may prevent chemical solutions (developer, etchant, or the like) used in the manufacturing process of the touch sensor metal arranged on the touch buffer layer 191 or external moisture from penetrating into the light-emitting layer 172 including organic materials. Accordingly, the touch buffer layer 191 may prevent damage to the light-emitting layer 172, which is vulnerable to chemical solutions or moisture.

The touch buffer layer 191 is formed of an organic insulating material, which is able to be formed at a low temperature of less than a predetermined temperature (e.g., 100 degrees C.) and has a low permittivity of 1 to 3, in order to prevent or at least reduce damage to the light-emitting layer 172 including an organic material that is vulnerable to high temperature. For example, the touch buffer layer 191 may be formed of an acrylic-based, epoxy-based, or siloxane-based material. The touch buffer layer 191 made of an organic insulating material and having a planarization property may prevent damage to the encapsulating layer 180 and the breakage of the touch sensor metal formed on the touch buffer layer 191 due to warping of the organic light-emitting display device.

According to a mutual-capacitance-based touch sensor structure, touch electrodes 195 and 196 may be disposed on the touch buffer layer 191, and the touch electrodes 195 and 196 may be arranged so as to intersect each other.

The touch electrode connecting lines 192 and 194 may electrically connect the touch electrodes 195 and 196 to each other. The touch electrode connecting lines 192 and 194 and the touch electrodes 195 and 196 may be located in different layers with a touch insulating layer 193 interposed therebetween.

The touch electrode connecting lines 192 and 194 are disposed to overlap the bank layer 165 so as to prevent an aperture opening ratio from deteriorating.

Meanwhile, the touch electrodes 195 and 196 may be electrically connected to a touch driving circuit (not illustrated) through a touch pad 198 as a part of the touch electrode connecting line 192 passes over an upper portion and a side surface of the encapsulating layer 180 and an upper portion and a side surface of the dam DAM.

A part of the touch electrode connecting line 192 may receive a touch driving signal from the touch driving circuit, and may transmit the same to the touch electrodes 195 and 196, or may transmit a touch sensing signal from the touch electrodes 195 and 196 to the touch driving circuit.

A touch protection layer 197 may be arranged on the touch electrodes 195 and 196. In the drawing, the touch protection layer 197 is illustrated as being arranged only on the touch electrodes 195 and 196, but is not limited thereto, and may be extended to the front or back of the dam DAM so as to be arranged on the touch electrode connecting line 192.

In addition, a color filter (not illustrated) may be further disposed on the encapsulating layer 180 and the color filter may be located on the touch layer 190 or located between the encapsulating layer 180 and the touch layer 190.

As described with reference to FIGS. 3 to 5, the lower surface portion 210 may overlap the display panel 100. Therefore, the lower surface portion 210 may overlap a plurality of components of the display panel 100 (all the components stacked from the substrate 101 to the touch electrode 195) in FIG. 7.

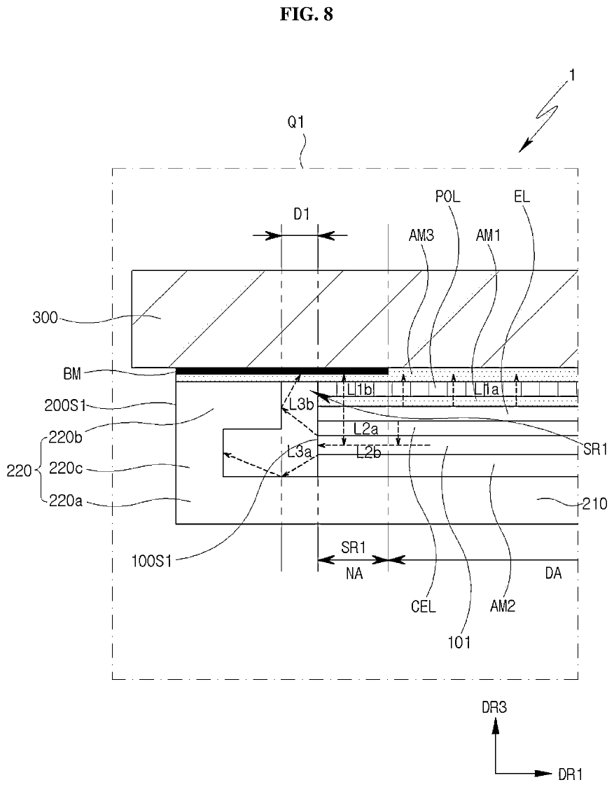

FIG. 8 is an enlarged cross-sectional view of a Q1 area in FIG. 4 according to one embodiment. In FIG. 8, the substrate 101 of the display panel 100, the circuit layer CEL, and the light-emitting diode layer EL are illustrated. As illustrated in FIG. 8, light L1a, L1b and L2a may be emitted on the light-emitting layer (refer to 172 of FIG. 7) of the organic light emitting diode OLED of the light-emitting diode layer EL. The first light L1a and L1b and L2a may include red light, green light, or blue light per pixel. The first light L1a and L1b are lights configured to be emitted upward from the light-emitting layer 172, and a second light L2a may be configured to be emitted downward. The first light L1a is emitted upward from the display area DA, and therefore, the first light L1a may proceed to the outside through the polarization member POL and the cover window 300. The first light L1b is emitted upward from the non-display area NA, and thus, the first light L1b may be absorbed through the first light-shielding pattern BM located in the non-display area NA, and may not proceed to the outside.

As illustrated in FIG. 8, a part of the second light L2a may be leaked through the side surface (for example, the first panel side surface 100S1 of the display panel 100) of the substrate 101. Though only the first panel side surface 100S1 and the first side surface portion 220 covering the first panel side surface 100S1 are illustrated in FIG. 8, it is apparent that the functions and structures of the second and the third side surface portions 230 and 240 covering the second panel side surface 100S2 and the third panel side surface 100S3, respectively, are the same as the functions and structures of the first side surface portion 220, which will be described below.

As described above, the substrate 101 is the rigid substrate, and includes glass or quartz, and therefore, the optical transmittance of the substrate 101 may be higher than that of the substrate including a flexible material. A thickness of the substrate 101 including the rigid material may be greater than that of the substrate including a flexible material. Therefore, compared to the flexible substrate, a ratio of leakage of the second light L2a through the side surface of the substrate 101 may be very high. Hereinafter, light of the second light L2a being leaked through the side surface of the substrate 101 is referred to third lights L3a and L3b. A phenomenon by which light is leaked through the side surface of the substrate 101 may be referred to as light leakage.

The side surface portion 220 may have a U-shape. The second side surface portion 220 may include a first portion 220a connected to the lower surface portion 210, a second portion 220b opposite to the first portion 220a, and a third portion 220c connecting the first portion 220a and the second portion 220b to each other. Each of the first and the second portions 220a and 220b may extend along the first direction DR1, and the third portion 220c may extend along the third direction DR3. In an embodiment, the first portion 220a, the second portion 220b and the third portion 220c may be formed by bending an edge portion of the plate 200. More specifically, an angle between the first portion 220a and the second portion 220b and an angle between the second portion 220b and the third portion 220c may be 90°.

The first side surface portion 220 is disposed outside the first panel side surface 100S1, and covers the first panel side surface 100S1 on the side surface, a part L3a of the third lights L3a and L3b leaked from the first panel side surface 100S1 (or the side surface of the first substrate 101) may be shielded by the first side surface portion 220, and may not be leaked to the outside of the display device 1. In an embodiment, “shield” may be a concept which includes reflection or absorbance.

In addition, the other part L3b of the third lights L3a and L3b may be shielded by the first light shielding pattern BM while proceeding to an interval space SR1 between the second portion 220b and the first side surface portion 100S1 of the display panel 100.

As described above, according to an embodiment, the first side surface portion 220 is disposed outside the first panel side surface 100S1, and covers the first panel side surface 100S1 on the side surface, and thus, a part L3a of the third lights L3a and L3b leaked from the first panel side surface 100S1 (or the side surface of the first substrate 101) is shielded by the first side surface portion 220 and may not be leaked to the outside of the display device 1. As described above, the plate is disposed (refer to 200 in FIG. 4) below the display panel 100, and may serve to support the display panel 100, and dissipate heat generated from the display panel 100 to the outside. In addition, the plate 200 further includes the first side surface portion 220 extending outward more from the side surface of the display panel 100 and integrally formed with the lower surface portion 210, and therefore, it is advantageous to prevent light leakage without adding any members such as an additional housing etc. for preventing the leakage from the side surface of the first substrate 101. Also, there is an effect of simplifying constituent components of the display device 1 and reducing material costs because any more members such as an additional housing etc. for preventing the light leakage are not needed.

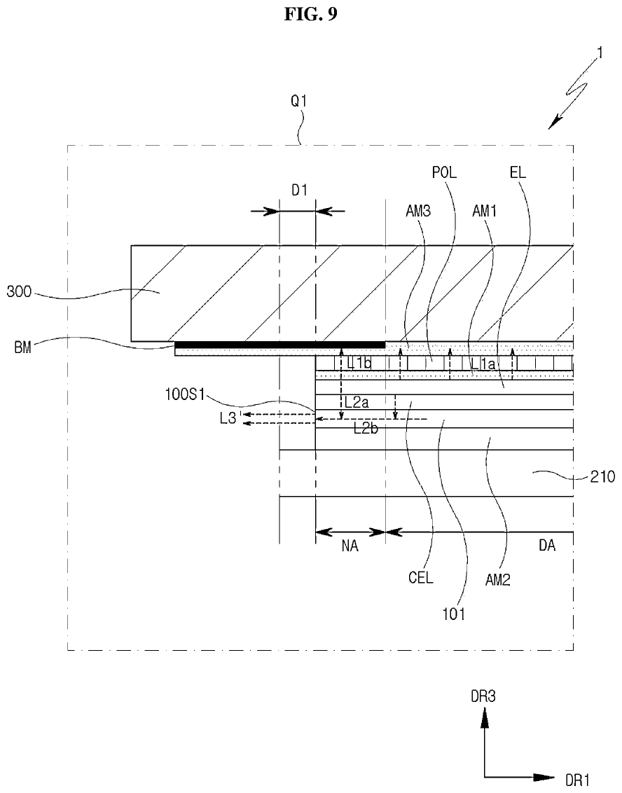

FIG. 9 is a cross-sectional view of the display device according to a comparative embodiment. A plate according to FIG. 9 is different from the plate 200 according to FIGS. 2 and 8 because the plate according to FIG. 9 does not include the side surfaces 210 to 230 according to FIGS. 2 and 8.

Referring to FIGS. 8 and 9, the plate according to FIG. 9 includes the lower surface portion 210 only, and therefore, there may be no member configured to cover the first panel side surface 100S1. Therefore, a third light L3′ leaked from the first panel side surface 100S1 (or a side surface of the first substrate 101) may be leaked to the outside of the display device 1, as illustrated in FIG. 9, causing the phenomenon of light leakage.

However, according to the display device 1 according to an embodiment, the first side surface portion 220 of the plate 200 is disposed outside the first panel side surface 100S1, and covers the first panel side surface 100S1 on the side surface, a part L3a of the third lights L3a and L3b leaked from the first panel side surface 100S1 (or the side surface of the first substrate 101) is shielded by the first side surface portion 220, and may not be leaked to the outside of the display device 1, resulting in preventing the phenomenon of light leakage.

Hereinafter, a display device according to another embodiment will be described. Components which are the same as those of the embodiment which has been described above will be referred to as the same reference numerals, and the description thereof will be omitted or simplified.

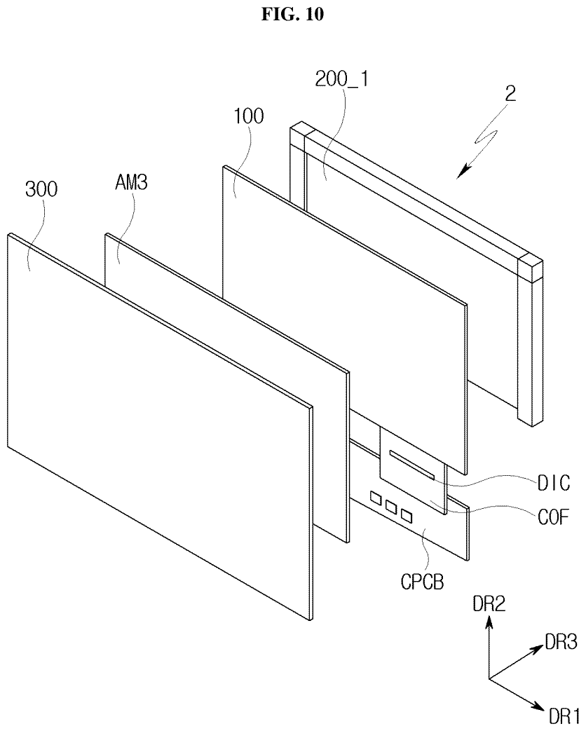

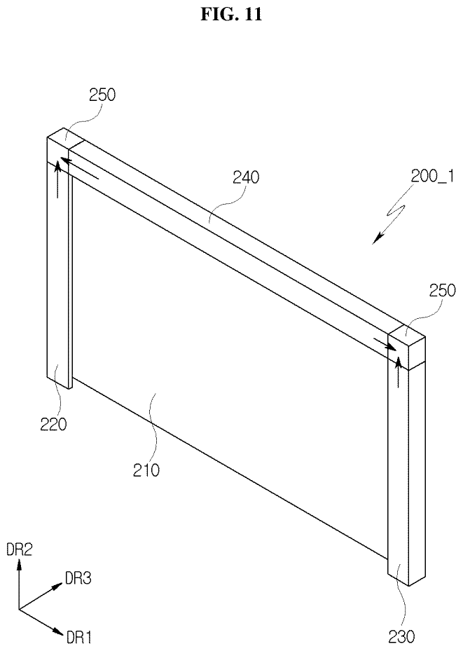

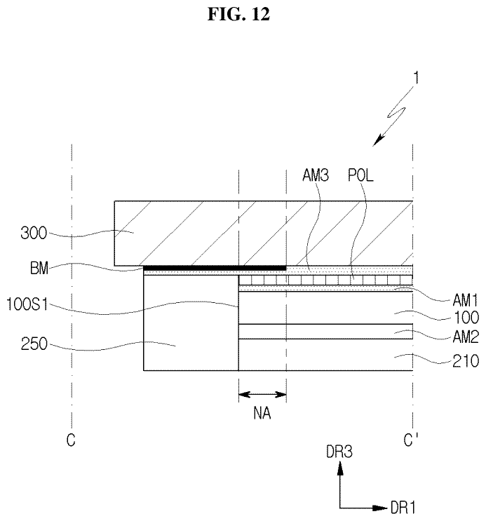

FIG. 10 is a perspective view of a display device according to another embodiment. FIG. 11 is a perspective view of a plate and a light-leaking prevention member of the display device according to FIG. 10 according to one embodiment. FIG. 12 is a cross-sectional view of the display device according to FIG. 10 according to one embodiment.

Referring to FIGS. 10 to 12, the display device 2 according to the present embodiment is different from the display device 1 according to FIGS. 1, 2 and 4 because the display device 2 according to the present embodiment may include a plate 200_1.

The plate 200_1 may further include a light-leaking prevention member 250 disposed between the first side surface portion 220 and the third side surface portion 240, and between the second side surface portion 230 and the third side surface portion 240. That is, an empty space may be formed at a corner portion between the first side surface portion 220 and the third side surface portion 240, and between the second side surface portion 230 and the third side surface portion 240. The light-leaking prevention members 250 may be disposed in empty spaces formed in edge portions (the edge portion on the other side in the first direction DR1 and on one side in the second direction DR2, the edge portion on one side in the first direction DR1 and on one side in the second direction DR2) of the lower surface portion 210. The light-leaking prevention members 250 may directly contact the adjacent side surface portions 220, 230 and 240.

The light-leaking prevention members 250 may prevent or at least reduce leakage of light leaked from the edge portions (the edge portion on the other side in the first direction DR1 and on one side in the second direction DR2, the edge portion on one side in the first direction DR1 and on one side in the second direction DR2) of the display panel 100 because the light-leaking prevention members 250 are disposed in empty spaces formed in the edge portions (the edge portion on the other side in the first direction DR1 and on one side in the second direction DR2, the edge portion on one side in the first direction DR1 and on one side in the second direction DR2) of the lower surface portion 210. To this end, the light-leaking prevention members 250 may include a light-shielding material. The light-shielding material may include a light-absorbing material.

Meanwhile, a coefficient of thermal expansion of the light-leaking prevention members 250 may be lower than each of coefficients of thermal expansion of the adjacent side surface portions 220, 230 and 240. For example, the coefficients of thermal expansion of the adjacent side surface portions 220, 230 and 240 may be about 30 ppm/° C. (part per million). In the present disclosure, a unit of ppm/° C. may mean a length (μm) which is changed whenever a temperature increases by 1° C. from 20° C.

The light-leaking prevention member 250 may include a material having a coefficient of thermal expansion lower than about 30 ppm/° C. For example, the light-leaking prevention members 250 may include rubber, or resin, but is not limited thereto.

The coefficient of thermal expansion of the light-leaking prevention member 250 according to the present embodiment is lower than the coefficients of thermal expansion the adjacent side surface portions 220, 230 and 240, as illustrated in FIG. 11. Therefore, if the side surface portions 220, 230 and 240 are thermally expanded by heat from the display panel 100 and lengths thereof are changed, the light-leaking prevention member 250 may buffer the length change. If the side surface portions 220, 230 and 240 are thermally expanded by heat from the display panel 100 and the length change occurs, physical interference may be generated between adjacent side surface portions 220, 230 and 240. However, the light-leaking prevention members 250 are disposed between the adjacent side surface portions 220, 230 and 240, and buffer the length change of the side surface portions 220, 230 and 240, thereby preventing or at least reducing the physical interference between the adjacent side surface portions 220, 230 and 240.

As illustrated in FIG. 12, the light-leaking prevention member 250 may directly contact the bonding member AM1, AM2 and AM3, the lower surface portion 210, the display panel 100, and the polarization member POL, but is not limited thereto.

Descriptions on other components have been provided with reference to FIGS. 1 to 8, and the detailed description thereof will be omitted.

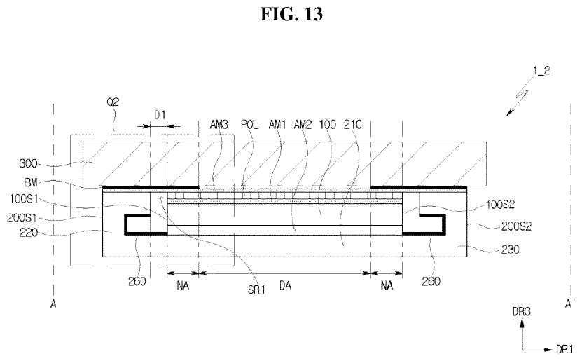

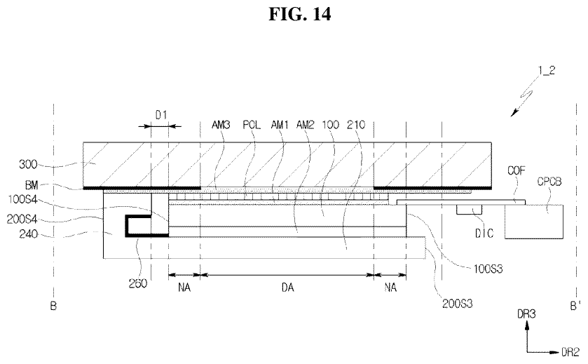

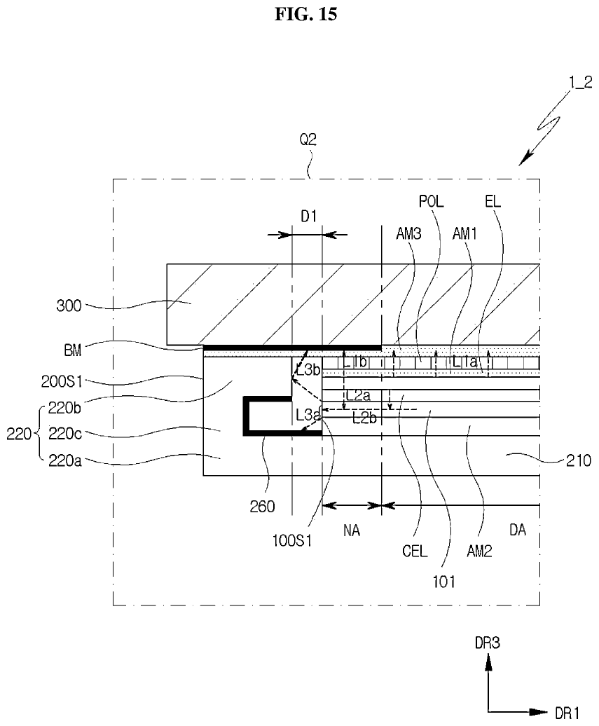

FIG. 13 is a cross-sectional view of a display device according to still another embodiment. FIG. 14 is a cross-sectional view of a display device according to still another embodiment. FIG. 15 is an enlarged cross-sectional view of a Q2 area in FIG. 13 according to one embodiment.

Referring to FIGS. 13 to 15, a display device 1_2 according to the present embodiment is different from the display device 1 according to FIGS. 4 and 5, because the display device 1_2 according to the present embodiment further includes an upper surface of the first portion 220a, a lower surface of the second portion 220b of the first side surface portion 220 of the plate (refer to 200 in FIG. 3), and a second light-shielding pattern 260 disposed on an inner side surface of the third portion 220c.

The second light-shielding pattern 260 may be disposed on an inner side surface of the first side surface portion 220, an inner side surface of the second side surface portion 230, and an inner side surface of the third side surface portion 240. The shapes of the side surface portions 220, 230 and 240 are the same, and it is apparent that the arrangement between the portions 220a, 220b and 220c of the first side surface portions 220 and the second light-shielding pattern 260 may be applied the same to the arrangement between the second and the third side surface portions 230 and 240 and the light shielding pattern. Hereinafter, for convenience of the description, only the arrangement relation between the first side surface portion 220 and the second light-shielding pattern 260 will be described.

The second light-shielding pattern 260 may include at least one among the materials exemplified as a material of the first light-shielding pattern BM, but is not limited thereto in case of including a light-shielding material.

As illustrated in FIG. 15, a part L3a of the third lights L3a and L3b leaked from the first panel side surface 100S1 (or the side surface of the first substrate 101) is shielded and absorbed by the second light-shielding pattern 260 and may not be leaked to the outside of the display device 1_2.

Descriptions on other components have been provided with reference to FIGS. 4 and 5, and the detailed description thereof will be omitted.

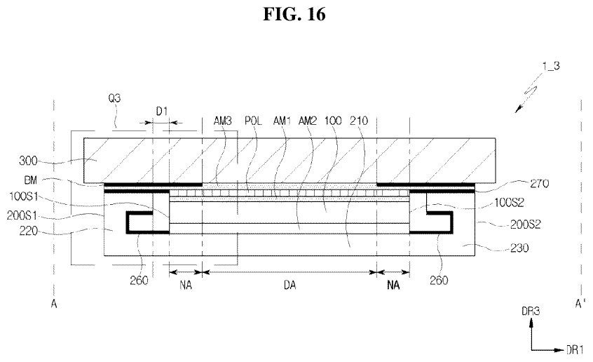

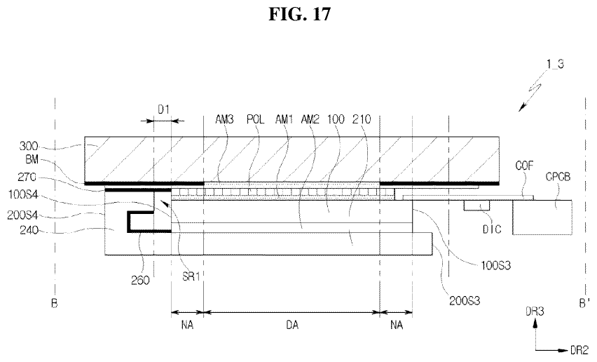

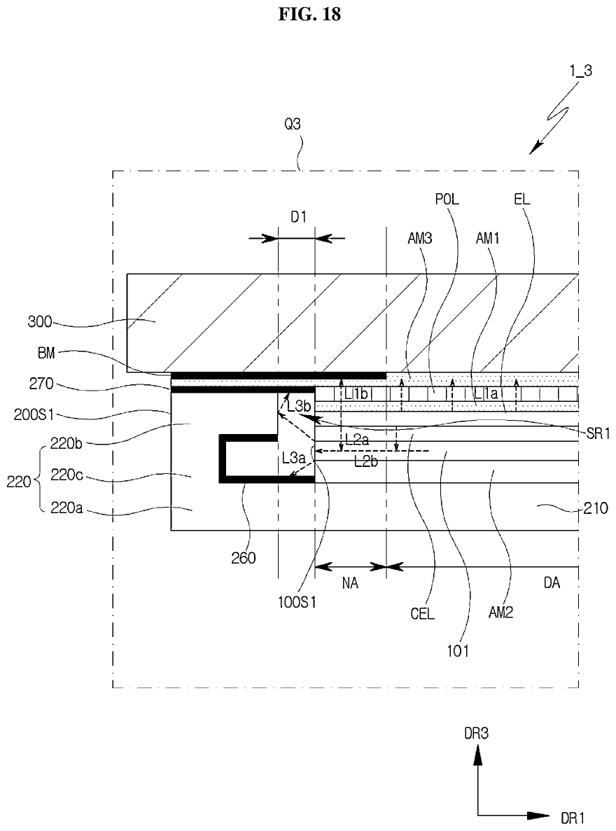

FIG. 16 is a cross-sectional view of a display device according to still another embodiment. FIG. 17 is a cross-sectional view of a display device according to still another embodiment. FIG. 18 is an enlarged cross-sectional view of a Q3 area in FIG. 16 according to one embodiment.

Referring to FIGS. 16 to 18, a display device 1_3 according to the present embodiment is different from the display device 1_2 according to FIGS. 13 to 15 because the display device 1_3 according to the present embodiment further includes a third light-shielding member 270 disposed between the side surface portions 220, 230 and 240 and the third bonding member AM3.

The third light-shielding member 270 may be disposed between each of the side surface portions 220, 230 and 240 and the third bonding member AM3, respectively. The third light-shielding member 270 may include one among the materials exemplified as a material of the first light-shielding pattern BM, but is not limited thereto in case of including a light-shielding material.

The third light-shielding member 270 may further cover an interval space SR1 between the second portion (refer to the second portion 220b of the first side surface portion 220) of each of the side surface portions 220, 230 and 240 and the panel side surfaces 100S1, 100S2 and 100S4 of the display panel 100.

As illustrated in FIG. 18, a part L3a of the third light L3a and L3b leaked from the first panel side surface 100S1 (or the side surface of the first substrate 101) is shielded and absorbed by the third light-shielding member 270 in the interval space SR1 and may not be leaked to the outside of the display device 1_3.

Descriptions on other components have been provided with reference to FIGS. 13 to 15, and the detailed description thereof will be omitted.

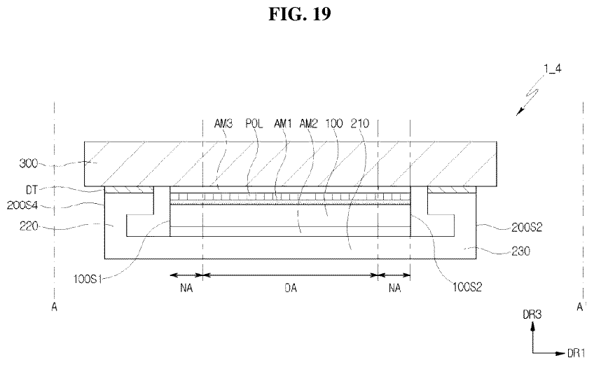

FIG. 19 is a cross-sectional view of a display device according to still another embodiment.

Referring to FIG. 19, a display device 1_4 according to the present embodiment is different from the display device 1 according to FIGS. 4 and 5 because the side surface portions of the plate (refer to 200 in FIG. 3) of the display device 1_4 according to the present embodiment are bonded to the cover window 300 through a double-sided tape DT.

Descriptions on other components have been provided with reference to FIGS. 4 and 5, and the detailed description thereof will be omitted.

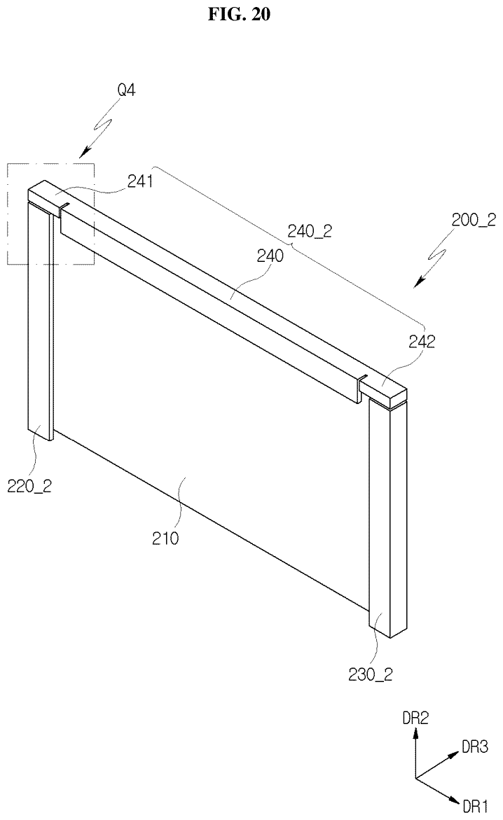

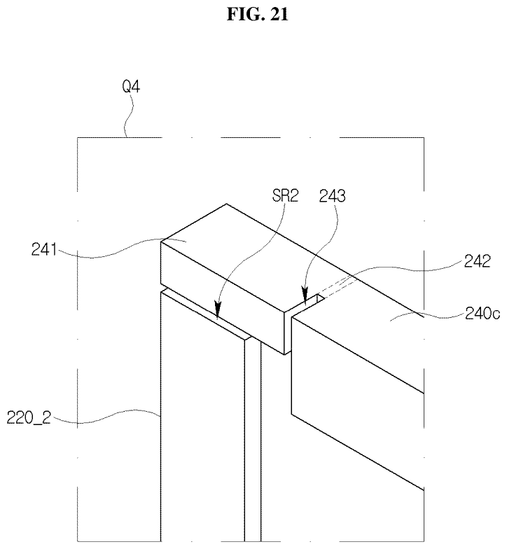

FIG. 20 is a perspective view of a plate according to still another embodiment. FIG. 21 is an enlarged perspective view of a Q4 area in FIG. 20.

Referring to FIGS. 20 and 21, a plate 200_2 according to the present embodiment is different from the plate 200 according to FIG. 2 because a third side surface portion 240_2 of the plate 200_2 according to the present embodiment extends more in the first direction DR1 toward adjacent first and second side surface portions 220_2 and 230_2.

In more detail, a third side surface portion 240_2 not only includes the third side surface portion 240 (hereinafter, a third main side surface portion 240) which has been described with reference to FIG. 2, but also may further include fourth and fifth portions 241 and 242. The third main side surface portion 240 may have the same structure as that of the third side surface portion 240 described referring to FIG. 2. The fourth and fifth portions 241 and 242 may be the portions of the third side surface portion 240 which extend in one and the other directions of the first direction DR1. That is, each of the fourth and fifth portions 241 and 242 may be provided two in number. Each of the fourth portions 241 extends toward the first side surface portion 220_2 and the second side surface portion 230_2, respectively, and may overlap the first side surface portion 220_2 and the second side surface portion 230_2, respectively. The fourth portion 241 may have a bar shape, but is not limited thereto, and may have a bent U-shape which is the same as the third main side surface portion 240. The fifth portion 242 may connect the fourth portion 241 and the third main side surface portion 240 to each other. A width of the fourth portion 241 in the third direction DR3 may be smaller than each of widths of the third main side surface portion 240 and the fourth portion 241 in the third direction DR3. In a space in which the fifth portion 242 is not disposed, the fourth portion 241 and the third main side surface portion 240 may be spaced apart from each other in the first direction DR1 (refer to 243 in FIG. 21).

Meanwhile, compared to the first and the second side surface portions 220 and 230 in FIG. 2, each of the first and the second side surface portions 220_2 and 230_2 may extend more toward one side in the second direction DR2. Each of ends of the first and the second side surface portions 220_2 and 230_2 extended more toward one side in the second direction DR2 may be spaced apart from the fourth portion 241, with a second interval space SR2 interposed therebetween.

The plate 200_2 of the display device according to the present disclosure has advantage in minimizing the phenomenon of light leakage generated in the edge portions (the edge portion on the other side in the first direction DR1 and on one side in the second direction DR2, the edge portion on one side in the first direction DR1 and on one side in the second direction DR2) of the lower surface portion 210, by forming the fourth portions 241 in the edge portions (the edge portion on the other side in the first direction DR1 and on one side in the second direction DR2, the edge portion on one side in the first direction DR1 and on one side in the second direction DR2) of the lower surface portion 210 and extending each of the first and the second side surface portions 220_2 and 230_2 more toward one side in the second direction DR2.

Descriptions on other components have been provided with reference to FIG. 2, and the detailed description thereof will be omitted.

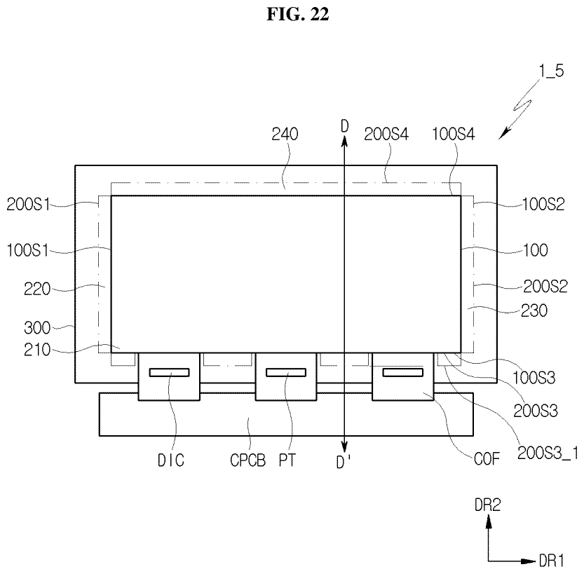

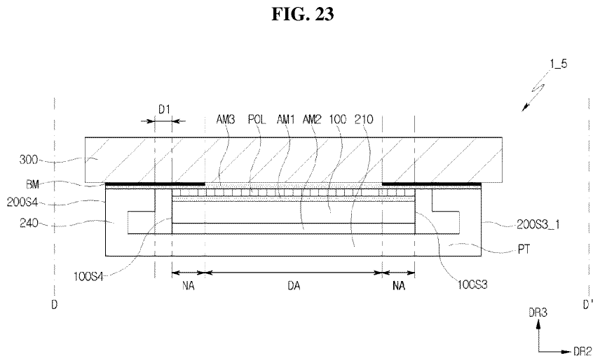

FIG. 22 is a plan view of a display device according to still another embodiment. FIG. 23 is a cross-sectional view taken along the line D-D′ in FIG. 22 according to one embodiment.

Referring to FIGS. 22 and 23, a display device 1_5 according to the present embodiment is different from the display device 1 according to FIG. 3 because a plate of the display device 1_5 according to the present embodiment further includes a protrusion PT on the long side of the lower surface portion 210, located on the other side of the second direction DR2.

A shape (a U-shape) and arrangement of the protrusion PT is the same as those of the side surface portions 220, 230 and 240, except that the protrusion PT is located on the long side on the other side of the second direction DR2, therefore, the detailed description thereof will be omitted.

The protrusion PT may be disposed between the adjacent printed circuit films COF. In addition, the protrusion PT may be provided in plurality. The printed circuit film COF may be disposed between the adjacent protrusions PT.

A side surface 200S3_1 of the protrusion PT may be disposed more outside in the first direction DR1 than the side surface on the long side on the other side of the second direction DR2 of the lower surface portion in which the protrusion PT is not formed. The side surface 200S3_1 of the protrusion PT may be disposed more outside than the third panel side surface 100S3 of the display panel 100, and the protrusion PT may cover the third panel side surface 100S3 of the display panel 100.

According to the present embodiment, no physical interference occurs with the printed circuit film COF by disposing the protrusion PT between the adjacent printed circuit films COF, and it is possible to improve the phenomenon of light leakage because the protrusion PT covers the third panel side surface 100S3 on the long side of the lower surface portion 210, which is on the other side of the second direction DR2.

Descriptions on other components have been provided with reference to FIG. 3, and the detailed description thereof will be omitted.

From the foregoing description of the embodiments with reference to accompanying drawings, those skilled in the art to which this invention pertains can understand that the present invention may be embodied in other specific forms without changing the technical spirit or essential characteristics of the invention. In this connection, the above-described embodiments should be understood as exemplary and as not limiting in all aspects. The scope of the present disclosure is represented by the appended claims, rather than the foregoing detailed description. In addition, all changes or modified forms derived from the meaning and range of the appended claims and the equivalents thereof are included in the scope of the present disclosure.

### REFERENCE NUMERALS

1: display device
100: displace panel
200, 200_1, 200_2: plate
300: cover window
AM1, AM2, AM3: bonding member
COF: printed circuit film
CPCB: source printed circuit board
DIC: data driver
210: lower surface portion
220, 220_1, 220_2: first side surface portion
230, 230_1, 230_2: second side surface portion
240, 240_1, 240_2: third side surface portion
250: light-leaking prevention member
BM: first light-shielding pattern
260: second light-shielding pattern
270: third light-shielding pattern
SR1: first interval space
SR2: second interval space.

What is claimed is:

1. A display device, comprising:
a display panel; and
a plate comprising a lower surface portion on a lower surface of the display panel and side surface portions connected to the lower surface portion and on side surfaces of the display panel,
wherein the side surface portions are on at least three side surfaces of the display panel.

2. The display device of claim 1, wherein the side surface portions comprise a first portion extending from the lower surface portion, a second portion opposite to the first portion, and a third portion that connects the first portion and the second portion.

3. The display device of claim 2, wherein the second portion is spaced apart from the side surfaces of the display panel in a plan view of the display device.

4. The display device of claim 3, further comprising:
a cover window on an upper surface of the display panel, the cover window extending outward more than the side surfaces of the display panel,
wherein the second portion is attached to the cover window.

5. The display device of claim 4, wherein the display panel further comprises:
a display area including a plurality of pixels;
a non-display area outside the display area; and
a first light-shielding pattern overlapping the non-display area on a lower surface of the cover window.

6. The display device of claim 5, further comprising:
a bonding member between the display panel and the cover window, the bonding member bonding the second portion and the first light-shielding pattern to each other.

7. The display device of claim 6, further comprising:
a second light-shielding pattern on an upper surface of the first portion, a lower surface of the second portion, and an inner side surface of the third portion.

8. The display device of claim 7, further comprising:
a third light-shielding pattern between the second portion and the bonding member, the third light-shielding pattern overlapping an interval space between the second portion and the side surfaces of the display panel.

9. The display device of claim 4, further comprising:
a double-sided tape between the second portion and the cover window,
wherein the second portion is attached to the cover window through the double-sided tape.

10. The display device of claim 2, wherein the side surface portions comprise:
a first side surface portion on a first side surface of the display panel; and
a second side surface portion on a second side surface of the display panel that is adjacent to the first side surface of the display panel, and
a light-leaking prevention member contacting each of the first side surface and the second side surface.

11. The display device of claim 10, wherein a coefficient of thermal expansion of the light-leaking prevention member is less than a coefficient of thermal expansion of the plate.

12. The display device of claim 11, wherein the light-leaking prevention member comprises rubber or a resin.

13. The display device of claim 10, wherein the second side surface portion further comprises a fourth portion on the first side surface portion, and a fifth portion that connects the third portion and the fourth portion to each other, and a second interval space is between the fourth portion and the third portion.

14. The display device of claim 13, wherein a third interval space is between the fourth portion and the first side surface portion.

15. The display device of claim 1, further comprising:
a flexible circuit film attached on one side surface of the display panel,
wherein the side surface portions are on side surfaces of the display panel except the one side surface.

16. The display device of claim 1, further comprising:
a flexible circuit film attached on one side surface of the display panel,
wherein the side surface portions are on side surfaces of the display panel comprising the one side surface.

17. The display device of claim 16, wherein the flexible circuit film includes a plurality of flexible circuit films, and the side surface portions on the one side surface is between the plurality of flexible circuit films that are adjacent to each other.

18. The display device of claim 17, wherein the side surface portions on the one side surface are non-overlapping the flexible circuit film.

19. A display device, comprising:
an organic light-emitting display panel comprising a rigid substrate and a light-emitting diode layer on the rigid substrate; and
a plate comprising a lower surface portion on a lower surface of the organic light-emitting display panel and side surface portions connected to the lower surface portion and on side surfaces of the organic light-emitting display panel,
wherein light generated from the light-emitting diode layer leaks through a side surface of the rigid substrate, and
wherein the side surface portions cover the side surface of the rigid substrate.

20. The display device of claim 19, wherein the rigid substrate comprises glass or quartz.
